(19) United States
(12) Patent Application Publication
(10) Pub. No.: US 2026/0016522 A1
(43) Pub. Date: Jan. 15, 2026

(54) SYSTEM AND METHOD FOR CHARACTERIZING A THREE-PHASE POWER SYSTEM USING NEUTRAL CURRENT INJECTION

(71) Applicant: SWITCHED SOURCE PB, LLC, VESTAL, NY (US)

(72) Inventors: Stanton Terry Cady, La Grange Park, IL (US); Matthew Peter Magill, Chevy Chase, MD (US); Charles James Murray, Palos Heights, IL (US)

(73) Assignee: SWITCHED SOURCE PB, LLC, VESTAL, NY (US)

(21) Appl. No.: 19/264,012

(22) Filed: Jul. 9, 2025

Related U.S. Application Data
(60) Provisional application No. 63/669,890, filed on Jul. 11, 2024.

(51) Int. Cl. G01R 31/08; G01R 19/10

(52) U.S. Cl. CPC G01R 31/086; G01R 19/10; G01R 31/088

(57) ABSTRACT

A system and method of identifying the source in a three-phase power system, wherein a zero-sequence circuit is coupled between the phase lines and the neutral line at a point of interconnection. The zero-sequence circuit to: (i) injects a known shunt current change into the point of interconnection and (ii) ceases injection of the known shunt current change into the point of interconnection. Neutral current values are obtained while the known shunt current change is injected and at least one of (i) before the known shunt current change is injected and (ii) after the known shunt current change is injected and ceased. A determination is made as to whether the source is on the first side of the point of interconnection or the second side of the point of interconnection based on the known shunt current change and the neutral current values.

### CROSS REFERENCE TO RELATED APPLICATIONS

This application claims priority to U.S. Provisional Patent Application Ser. No. 63/669,890, filed on Jul. 11, 2024, and titled “System and Method for Characterizing a Three-Phase Power System Using Neutral Current Injection,” the disclosure of which is incorporated herein by reference.

### FIELD OF THE INVENTION

The disclosed concept relates generally to three-phase power systems, and, in particular, to a system and method for characterizing various aspects of a three-phase power system based on neutral current injection. For example, in one aspect, the disclosed concept relates to a system and method for identifying a source in a three-phase power system based on neutral current injection.

### BACKGROUND OF THE INVENTION

An electrical power system normally operates in a balanced three-phase sinusoidal steady-state mode. However, there are certain situations that can cause unbalanced operations. The most severe of these would be a fault or short circuit. Examples may include a tree in contact with a conductor, a lightning strike, or a downed power line. The basic theory of symmetrical components is that phase currents and voltages in a three-phase power system including three phase lines and a neutral line can be represented by three single-phase components. These are positive-, negative- and zero-sequence components. The positive sequence component of current or voltage has the same rotation as the power system. This component represents a balanced load.

If the generator phase currents are equal and displaced by exactly 120°, only positive-sequence current will exist. An imbalance between the magnitude or phase angle of current or voltage between phases gives rise to negative- and zero-sequence components. The negative sequence component has a rotation opposite that of the power system. The zero-sequence component represents an imbalance that causes current flow in the neutral. A driver of these imbalances is the use of single-phase laterals, where one medium voltage phase of a circuit is extended to feed groups of single-phase customers, a block of homes or a subdivision at a time, for example.

Unlike positive- and negative-sequence phase currents, which are each displaced by 120° in a three-phase system, zero-sequence currents are each displaced by 0° and are therefore “in-phase.” As a result, zero-sequence currents combine arithmetically at the source transformer's neutral terminal and return to the loads via the system's neutral conductor. In a worst-case scenario, the resulting zero-sequence neutral currents may be greater than 1.5 times the phase currents.

Zero-sequence currents, acting in an Ohm's Law relationship with the system's zero-sequence impedances, produce zero-sequence voltages. These zero-sequence voltages distort the fundamental voltage waveforms. Systems and methods for alleviating fundamental frequency line load imbalance in the distribution system will thus reduce line loss and increase power system capacity without installing new lines.

Systems and methods for reducing zero-sequence current in a three-phase power system are therefore desirable. Examples of such systems and methods are described in U.S. Pat. Nos. 11,056,883 and 11,296,509, the disclosures of which are incorporated herein by reference. These exemplary systems include a zig-zag transformer and at least one Cascade Multilevel Modular Inverter (CMMI) that is coupled between the distribution system and the neutral. A controller modulates the states of the H-bridges in the CMMI to build an AC waveform. The voltage is chosen by the controller in order to control an equivalent impedance that draws an appropriate neutral current through the zig-zag transformer. This neutral current is generally chosen to cancel the neutral current sensed in the line. In other embodiments, the chosen neutral current may be based on a remotely sensed imbalance, rather than on a local value, determined by the power utility as a critical load point in the system.

In electrical power systems, for many reasons it is often necessary to accurately identify the location of the source in the system. For example, for properly reducing zero-sequence current as described above, the dominant source and load side must be accurately identified. In the field, however, it can be difficult to do so from just a set of distribution wires. Also, while in the past electrical power systems were fairly static, with power flows in one direction, that is changing. More recently, the power grid is becoming more complex, with some systems being bi-directional and/or including multiple generators or other sources. Also, electrical utilities are devising ways to reconfigure their grids, such as by feeding circuits from multiple substations, so that the grid can be transitioned when needed, such as during a storm or for maintenance. The configuration of modern electrical power systems, therefore, is becoming more dynamic, and the topology thereof changes from time to time depending on a variety of factors.

There is thus a need for a methodology and approach for accurately identifying the source and the load side at a particular interconnection point within electrical power systems at any particular point in time. In addition, more generally, there is also a need for methodology and approach for characterizing various other aspects of a three-phase power system.

### SUMMARY

In one embodiment, a method of identifying a source in a three-phase power system including three phase lines and a neutral line is provided, wherein a zero-sequence circuit is coupled between the three phase lines and the neutral line at a point of interconnection and is configured to inject current into the point of interconnection. The method includes causing the zero-sequence circuit to: (i) inject a known shunt current change into the point of interconnection and (ii) cease injection of the known shunt current change into the point of interconnection, obtaining neutral current values while the known shunt current change is injected and at least one of (i) before the known shunt current change is injected and (ii) after the known shunt current change is injected and ceased, and determining whether the source is on the first side of the point of interconnection or the second side of the point of interconnection based on the known shunt current change and the neutral current values.

In another embodiment, a system for identifying a source in a three-phase power system including three phase lines and a neutral line is provided. The system includes a zero-sequence circuit coupled between the three phase lines and the neutral line at a point of interconnection, wherein the zero-sequence circuit is configured to inject current into the point of interconnection, and a controller coupled to the zero-sequence circuit. The controller is structured and configured for: causing the zero-sequence circuit to: (i) inject a known shunt current change into the point of interconnection and (ii) cease injection of the known shunt current change into the point of interconnection; obtaining neutral current values while the known shunt current change is injected and at least one of (i) before the known shunt current change is injected and (ii) after the known shunt current change is injected and ceased; and determining whether the source is on the first side of the point of interconnection or the second side of the point of interconnection based on the known shunt current change and the neutral current values.

### BRIEF DESCRIPTION OF THE DRAWINGS

A full understanding of the invention can be gained from the following description of the preferred embodiments when read in conjunction with the accompanying drawings in which:

FIG. 1 is a schematic diagram showing a system for minimizing zero-sequence current and for identifying a source in a three-phase distribution circuit according to an exemplary embodiment of one aspect of the disclosed concept;

FIG. 2 is a flowchart illustrating a source detection method according to an exemplary embodiment of the disclosed concept;

FIG. 3 is a schematic diagram illustrating the shunt current (inₛₕₜ), the neutral current (inₑₓₜ₁), and the neutral current (inₑₓₜ₂) according to an aspect of an exemplary embodiment of the disclosed concept; and

FIG. 4 is a schematic diagram showing a system for minimizing zero-sequence current and for identifying a source in a three-phase distribution circuit according to an alternative exemplary embodiment of one aspect of the disclosed concept.

### DETAILED DESCRIPTION OF THE INVENTION

As used herein, the singular form of “a”, “an”, and “the” include plural references unless the context clearly dictates otherwise.

As used herein, the statement that two or more parts or components are “coupled” shall mean that the parts are joined or operate together either directly or indirectly, i.e., through one or more intermediate parts or components, so long as a link occurs.

As used herein, “directly coupled” means that two elements are directly in contact with each other.

As used herein, the term “number” shall mean one or an integer greater than one (i.e., a plurality).

As used herein, the term “controller” shall mean a programmable analog and/or digital device (including an associated memory part or portion) that can store, retrieve, execute and process data (e.g., software routines and/or information used by such routines), including, without limitation, a field programmable gate array (FPGA), a complex programmable logic device (CPLD), a programmable system on a chip (PSOC), an application specific integrated circuit (ASIC), a microprocessor, a microcontroller, a programmable logic controller, or any other suitable processing device or apparatus. The memory portion can be any one or more of a variety of types of internal and/or external storage media such as, without limitation, RAM, ROM, EPROM(s), EEPROM(s), FLASH, and the like that provide a storage register, i.e., a non-transitory machine readable medium, for data and program code storage such as in the fashion of an internal storage area of a computer, and can be volatile memory or nonvolatile memory.

Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

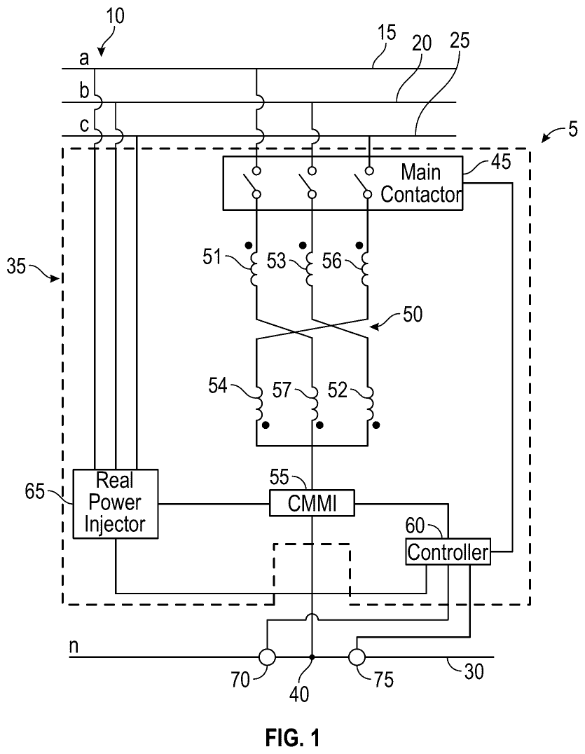

FIG. 1 is a schematic diagram showing a system 5 for minimizing zero-sequence current and for identifying a source in a three-phase distribution circuit 10 according to an exemplary embodiment of one aspect of the disclosed concept. As seen in FIG. 1, distribution circuit 10 includes a phase A line 15, a phase B line 20, a phase C line 25, and a neutral line 30. In addition, system 5 includes a zero-sequence circuit 35 that is coupled between the three phase lines 15, 20, 25 and neutral line 30 at a point of interconnection 40 of neutral line 30. Zero-sequence circuit 35 is structured and configured to balance real and reactive power across the three phases of distribution circuit 10 by reducing imbalances in phase currents and voltages, including by minimizing current flowing within neutral line 30.

As seen in FIG. 1, in the non-limiting exemplary embodiment, zero-sequence circuit 35 includes a main contactor 45, a zig-zag transformer 50, and a shunt cascade multilevel modular inverter (CMMI) 55 that are connected in series as shown. Zig-zag transformer 50 has six windings: 51, 52, 53, 54, 55 and 22. Zero-sequence circuit 35 is configured to inject a shunt current (inₛₕₜ) into the point of interconnection 40 (which may or may not be locally connected to earth ground) under the control of a controller 60 that is coupled to zero-sequence circuit 35. In particular, in the exemplary embodiment, controller 60 implements: (i) a neutral current controller module that is configured to use local and remote current and voltage measurements to generate a desired shunt current injection (into point of interconnection 40) that would minimize the source neutral current, and (ii) a shunt current regulator module that is configured to generate a voltage command for CMMI 55 necessary to generate the desired shunt current injection. In addition, in the illustrated exemplary embodiment, zero-sequence circuit 35 includes a real power injector circuit 65 as described in, for example, U.S. Pat. No. 11,296,509. As seen in FIG. 1, real power injector circuit 65 is provided between the three-phase lines 15, 20, 25 and CMMI 55. Real power injector circuit is structured and configured to cause real power to be injected into the CMMI to regulate a voltage of one or more of the module capacitors of the CMMI.

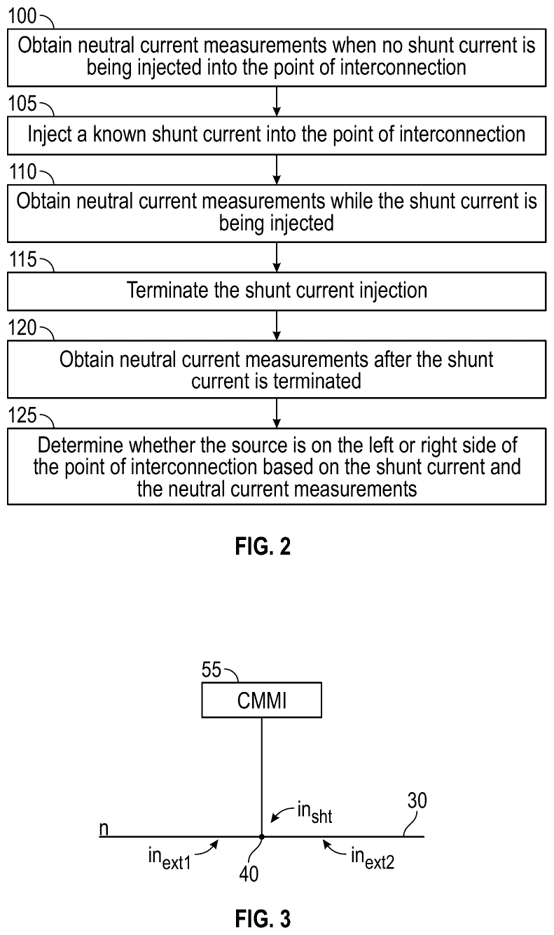

Furthermore, in the exemplary embodiment, system 5 also includes a first local current sensor 70 that is external to zero-sequence circuit 35 for measuring the neutral current (inₑₓ₁) on the left side of point of interconnection 40, and a second local current sensor 75 that is external to zero-sequence circuit 35 for measuring the neutral current (inₑₓₜ₂) on the right side of point of interconnection 40. These measured neutral current values are provided to controller 60. The shunt current (inₛₕₜ), the neutral current (inₑₓₜ₁), and the neutral current (inₑₓₜ₂) are illustrated in FIG. 3. The neutral current values, along with information regarding the shunt current that is injected, are used for identifying which side of point of interconnection 40 is the source side and which side of point of interconnection 40 is the load side and any point in time as described elsewhere herein (FIG. 2). The current measurements made by current sensors 70, 75 may be in the time domain or in the phasor domain. In addition, in an alternative embodiment, the current measurements needed to identify the source and load as described herein may, rather than being measured locally, instead come from a remote source, in which case current sensors 70, 75 may be omitted. In addition, in an alternative embodiment, only one external current measurement, instead of two, are used to identify the source and load as described herein.

FIG. 2 is a flowchart illustrating a source detection method according to an exemplary embodiment of the disclosed concept for determining at any particular time which side of point of interconnection 40 is the source side distribution circuit 10 and which side of point of interconnection 40 is the load side based on the network response (specifically the neutral current response) to controlled current injections at point of interconnection 40. As noted elsewhere herein, this source detection/identification functionality is advantageous for proper determination of substation (and power flow) direction to allow for proper network phase balancing in distribution circuit 10. In the exemplary embodiment, the method of FIG. 2 is implemented in a number of routines stored by and executable by controller 60.

Referring to FIG. 2, the method begins at step 100, wherein, at time t0, external neutral currents before known shunt current injection are recorded. In the non-limiting exemplary embodiment, this step involves obtaining measurements from current sensors 70, 75 of the neutral current on both the left side (inₑₓ₁) and the right side (inₑₓₜ₂) of point of interconnection 40 when no shunt current is being injected into point of interconnection 40 (inₛₕₜ=0). If the currents are measured in the phasor domain, for example, this step may be represented as follows:

$${}_{sht}^{t 0} = 0$$

$$Measure {}_{ext 1}^{t 0} , {}_{ext 2}^{t 0} .$$

It will be appreciated that the same relationships may also be used in embodiments where the currents are measured in the time domain. Next, at step 105, at time 11, a known shunt current is injected into the point of interconnection 40 by controlling CMMI 55 with appropriate voltages by way of a voltage command from controller 60. The known shunt current that is injected into the point of interconnection 40 may be superimposed on a another current that is being injected the point of interconnection 40 for some other purpose, such as for reducing the neutral current supplied by the source. Then, at step 110, external neutral currents during known shunt current injection are recorded. In the non-limiting exemplary embodiment, this step involves obtaining measurements from current sensors 70, 75 of the neutral current on both the left side (inₑₓₜ₁) and the right side (inₑₓₜ₂) of point of interconnection 40 while the shunt current is being injected. If the currents are measured in the phasor domain, for example, this step may be represented as follows:

$${}_{sht}^{t 1} = {In}_{sht} ∠ {θ}_{sht}$$

$$Measure {}_{ext 1}^{t 1} , {}_{ext 2}^{t 1} .$$

It will be appreciated that the same relationships may also be used in embodiments where the currents are measured in the time domain. Next, at step 115, at time t2, the shunt current injection is terminated and no current is being injected into point of interconnection 40 (inₛₕₜ=0). Then, at step 120, external neutral currents after known shunt current injection are recorded. In the non-limiting exemplary embodiment, this step involves obtaining measurements from current sensor 70, 75 of the neutral current on both the left side (inₑₓₜ₁) and the right side (inₑₓₜ₂) of point of interconnection 40 after the shunt current injection is terminated. If the currents are measured in the phasor domain, for example, this step may be represented as follows:

$${}_{sht}^{t 2} = 0$$

$$Measure {}_{ext 1}^{t 2} , {}_{ext 2}^{t 2} .$$

It will be appreciated that the same relationships may also be used in embodiments where the currents are measured in the time domain. Then, at step 125, a determination is made as to whether the source is on the left or right side of the point of interconnection 40 based on the known shunt current and the neutral current measurements at times t0, t1 and t2. In the exemplary embodiment, step 125 is performed by first calculating relative changes in the neutral currents (Δinₑₓₜ₁ and Δinₑₓₜ₂) as a result of the change in the shunt current (Δinₛₕₜ). If the currents are measured in the phasor domain, for example, this step may be represented as follows:

$$Δ {}_{sht} = {}_{sht}^{t 1}$$

$$Δ {}_{ext 1} = \frac{{}_{ext 1}^{t 0} + {}_{ext 1}^{t 2}}{2} - {}_{ext 1}^{t 1}$$

$$Δ {}_{ext 2} = \frac{{}_{ext 2}^{t 0} + {}_{ext 2}^{t 2}}{2} - {}_{ext 2}^{t 1} .$$

It will be appreciated that the same relationships may also be used in embodiments where the currents are measured in the time domain. Then, a sensitivity index (\tilde{γ}) is calculated for both the left side (\tilde{γ}ₑₓₜ₁) and the right side (\tilde{γ}ₑₓₜ₂) of point of interconnection 40, and the sensitivity indices are used to determine which side is the source and which side is the load. If the currents are measured in the phasor domain, for example, this step may be represented as follows:

$${\tilde{γ}}_{ext 1} = Δ {}_{ext 1} / Δ {}_{sht}$$

$${\tilde{γ}}_{ext 2} = Δ {}_{ext 2} / Δ {}_{sht} .$$

It will be appreciated that the same relationships may also be used in embodiments where the currents are measured in the time domain.

In one particular non-limiting exemplary embodiment, the source side is identified using these sensitivity indices as follows: if |\tilde{γ}ₑₓₜ₁|≥X|\tilde{γ}ₑₓₜ₂|, then the left side of point of interconnection 40 is identified as the source and the right side of point of interconnection 40 is identified as the load, and if |\tilde{γ}ₑₓₜ₂|≥X|\tilde{γ}ₑₓₜ₁|, then the right side of point of interconnection 40 is identified as the source and the right side of point of interconnection 40 is identified as the load, wherein X is a predetermined coefficient. If neither of these conditions is met, then the source detection evaluation is deemed to be indeterminate. In one particular, non-limiting implementation, X is 4. In another particular, non-limiting implementation, X is 10. It will be appreciated that other values for X may be used without departing from the scope of the disclosed concept.

In another, alternative particular non-limiting exemplary embodiment, the source side is identified using these sensitivity indices as follows: if |\tilde{γ}ₑₓₜ₁|≥X|\tilde{γ}ₑₓₜ₂| and if |\tilde{γ}ₑₓₜ₁|≥Y, then the left side of point of interconnection 40 is identified as the source and the right side of point of interconnection 40 is identified as the load, and if |\tilde{γ}ₑₓₜ₂|≥X|\tilde{γ}ₑₓₜ₁| and if |\tilde{γ}ₑₓₜ₂|≥Y, then the right side of point of interconnection 40 is identified as the source and the right side of point of interconnection 40 is identified as the load, wherein X is a predetermined coefficient and Y is a predetermined constant. In one particular, non-limiting implementation, X is 4 and Y is 0.6 or 0.5. In another particular, non-limiting implementation, X is 10 and Y is 0.6 or 0.5. It will be appreciated that other values for X and Y may be used without departing from the scope of the disclosed concept.

In addition, while particular embodiments described above rely on the measurement or receipt of a neutral current value on each side of point of intersection 40, it will be appreciated that that is meant to be exemplary only. In alternative embodiments, the source and load side detection as described herein may also be determined by measuring or receiving from a remote source the value of the neutral current only a single side of point of interconnection 40. In such an embodiment, Kirchhoff's law can be used to determine the other neutral current based on the known shunt current and the single measured or received neutral current value. since under Kirchhoff's law the sum of the current into and out of point of interconnection 40 must equal zero.

Furthermore, as described above, the source detection method of the disclosed concept is based on the network response, and specifically the neutral current response, to controlled current injections. In the exemplary embodiment shown in FIG. 2 and described herein, the controlled current injections are in the form of a transition from zero shunt current to a known shunt current and back to a zero-shunt current, with Δinₛₕₜ being equal to the known shunt current injection. It will be understood that this is meant to be exemplary, and that instead the controlled current injections may be in the form of a transition from first shunt current to a second shunt current and back to the first shunt current, with Δinₛₕₜ being equal to the difference between the first and second shunt currents.

Also, in the exemplary embodiments described above, the neutral currents on each side of point of interconnection 40 are obtained (i) before the known shunt current change is injected, (ii) while the known shunt current change is injected, and (iii) after the known shunt current change is injected and ceased. Those neutral currents (at three times) are then used to determine the neutral current changes in response to the current injection that are ultimately used to identify the source as described herein. This is meant to be exemplary of the disclosed concept and is not limiting. In a still further alternative embodiment, rather than obtaining the neutral current values at three times as just described, neutral currents values on each side of point of interconnection 40 are obtained at two times, namely (i) while the known shunt current change is injected, and (ii) either before or after the known shunt current change is injected. In this alternative embodiment, those neutral current values measured at just two times are then used to identify the source. Specifically, in this embodiment, the neutral current changes on each side of point of interconnection 40 responsive the current injection that are used to determine the sensitivities described herein and to identify the source as described herein are based on (i) the neutral current value while the shunt current is injected, and (ii) the neutral current value either before or after injection, as the case may be.

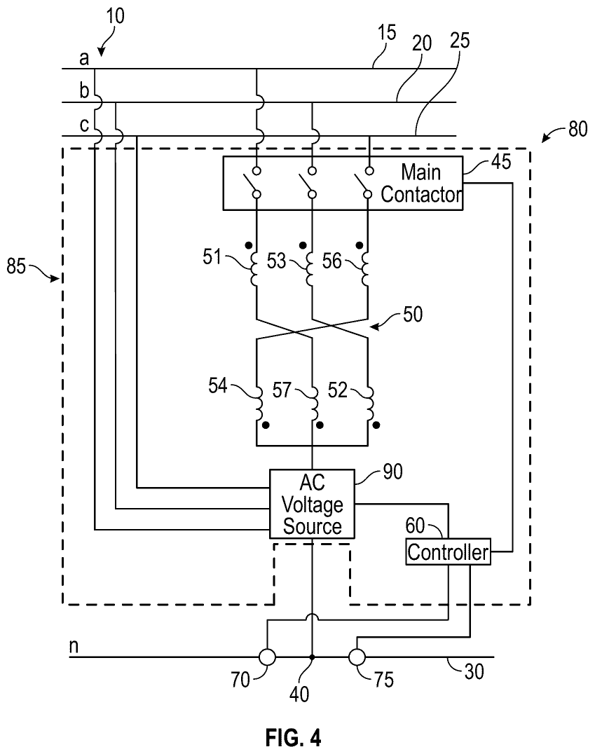

FIG. 4 is a schematic diagram showing a system 80 for minimizing zero-sequence current and for identifying a source in a three-phase distribution circuit 10 according to an alternative exemplary embodiment of one aspect of the disclosed concept. System 80 is similar to system 5, and like parts are labeled with like refence numerals. As seen in FIG. 4, distribution circuit 10 includes a phase A line 15, a phase B line 20, a phase C line 25, and a neutral line 30. In addition, system 80 includes a zero-sequence circuit 85 that is coupled between the three phase lines 15, 20, 25 and neutral line 30 at a point of interconnection 40 of neutral line 30. Zero-sequence circuit 85 is structured and configured to balance real and reactive power across the three phases of distribution circuit 10 by reducing imbalances in phase currents and voltages, including by minimizing current flowing within neutral line 30.

As seen in FIG. 4, in the non-limiting exemplary embodiment, zero-sequence circuit 85 includes a main contactor 45, a zig-zag transformer 50, and a controllable AC voltage source 90 that are connected in series as shown. Controllable AC voltage source 90 is also coupled to the three-phase lines 15, 20, 25. Controllable AC Voltage Source 90 takes as input the three phase power and outputs a single phase sinusoidal voltage. When this voltage is applied between the secondary of zigzag transformer 50 and the neutral of the grid, it allows for the device to inject a specified amount of zero sequence/neutral current. Put differently, the controllable AC Voltage Source+zigzag together form a controllable current injector.

Zig-zag transformer 50 has six windings: 51, 52, 53, 54, 55 and 22. As described above, zero-sequence circuit 85 is configured to inject a shunt current (inₛₕₜ) into the point of interconnection 40 (which may or may not be locally connected to earth ground) under the control of controller 60 that is coupled to zero-sequence circuit 85. In particular, in the exemplary embodiment, controller 60 implements: (i) a neutral current controller module that is configured to use local and remote current and voltage measurements to generate a desired shunt current injection (into point of interconnection 40) that would minimize the source neutral current, and (ii) a shunt current regulator module that is configured to generate a voltage command for controllable AC voltage source 90 necessary to generate the desired shunt current injection.

Furthermore, in the exemplary embodiment, system 80 also includes a first local current sensor 70 that is external to zero-sequence circuit 85 for measuring the neutral current (inₑₓₜ₁) on the left side of point of interconnection 40, and a second local current sensor 75 that is external to zero-sequence circuit 85 for measuring the neutral current (inₑₓₜ₂) on the right side of point of interconnection 40. These measured neutral current values are provided to controller 60. The neutral current values, along with information regarding the shunt current that is injected, are used for identifying which side of point of interconnection 40 is the source side and which side of point of interconnection 40 is the load side and any point in time as described elsewhere herein (e.g., FIG. 2). The current measurements made by current sensors 70, 75 may be in the time domain or in the phasor domain. In addition, in an alternative embodiment, the current measurements needed to identify the source and load as described herein may, rather than being measured locally, instead come from a remote source, in which case current sensors 70, 75 may be omitted. In addition, in an alternative embodiment, only one external current measurement, instead of two, are used to identify the source and load as described herein.

Moreover, the embodiments described thus far relate to source detection and identification in a three-phase power system based on controlled neutral current injection. Further aspects of the disclosed concept relate to other types of grid characterization via neutral current injection. In one aspect, the disclosed concept provides a system and method for substation control selection that includes (i) installing a monitoring device having neutral current injection capability, such as zero sequence circuit 35, in a highly reconfigurable 3-phase, 4-wire network, (ii) injecting a known neutral current in the point of interconnection of the device to the neutral conductor of the network, (iii) responsive to the neutral current injection, providing remote substation measurements, such as 3-phase voltage, 3-phase line current, and neutral current, to the device, and (iv) using the known neutral current injection and the received measurements to determine which substation is connected to the device to appropriately determine phase balancing control objective. Furthermore, continuous monitoring may be used to detect changes in network and load variations at each side of the interconnection point.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of disclosed concept which is to be given the full breadth of the claims appended and any and all equivalents thereof.

What is claimed is:

1. A method of identifying a source in a three-phase power system including three phase lines and a neutral line, wherein a zero-sequence circuit is coupled between the three phase lines and the neutral line at a point of interconnection and is configured to inject current into the point of interconnection, the method comprising:
causing the zero-sequence circuit to: (i) inject a known shunt current change into the point of interconnection and (ii) cease injection of the known shunt current change into the point of interconnection;
obtaining neutral current values while the known shunt current change is injected and at least one of (i) before the known shunt current change is injected and (ii) after the known shunt current change is injected and ceased; and
determining whether the source is on the first side of the point of interconnection or the second side of the point of interconnection based on the known shunt current change and the neutral current values.

2. The method according to claim 1, wherein the obtaining comprises obtaining values of first side neutral currents on a first side of the point of interconnection while the known shunt current change is injected and the neutral current values obtained either before or after the known shunt current change is injected and obtaining values of second side neutral currents on a second side of the point of interconnection while the known shunt current change is injected and the neutral current values obtained either before or after the known shunt current change is injected, and determining a first neutral current change based on the values of the first side neutral currents and a second neutral current change based on the values of the second side neutral currents, wherein the determining comprises determining whether the source is on the first side of the point of interconnection or the second side of the of the point of interconnection based on the known shunt current change and the first and second neutral current changes.

3. The method according to claim 1, wherein the obtaining comprises obtaining neutral current values: (i) before the known shunt current change is injected, (ii) while the known shunt current change is injected, and (iii) after the known shunt current change is injected and ceased.

4. The method according to claim 1, wherein the obtaining comprises obtaining values of first side neutral currents on a first side of the point of interconnection: (i) before the known shunt current change is injected, (ii) while the known shunt current change is injected, and (iii) after the known shunt current change is injected and ceased and obtaining values of second side neutral currents on a second side of the point of interconnection: (i) before the known shunt current change is injected, (ii) while the known shunt current change is injected, and (iii) after the known shunt current change is injected and ceased; and wherein the determining comprises determining whether the source is on the first side of the point of interconnection or the second side of the of the point of interconnection based on the known shunt current change, the values of the first side neutral currents and the values of the second side neutral currents.

5. The method according to claim 4, wherein the values of the first side neutral currents and the values of the second side neutral currents are each either measured by a current sensor or received from a remote source.

6. The method according to claim 4, wherein the values of the first side neutral currents are each either measured by a current sensor or received from a remote source, and wherein the values of the second side neutral currents are obtained using the first side neutral currents, the known shunt current and Kirchhoff's law.

7. The method according to claim 4, wherein the causing step, the obtaining steps and the determining step comprise:
obtaining values of a first neutral current on the first side of the point of interconnection and a second neutral current on the second side of the point of interconnection when no current is being injected into the point of interconnection;
injecting a shunt current having a known value into the point of interconnection and obtaining values of a third neutral current on the first side of the point of interconnection and a fourth neutral current on the second side of the point of interconnection during the injection of the shunt current;
terminating the injection of the shunt current and obtaining values of a fifth neutral current on the first side of the point of interconnection and a sixth neutral current on the second side of the point of interconnection when no current is being injected into the point of interconnection; and
determining whether the source is on the first side of the point of interconnection or the second side of the of the point of interconnection based on the shunt current, and the values of the first neutral current, the second neutral current, the third neutral current, the fourth neutral current, the fifth neutral current and the sixth neutral current.

8. The method according to claim 7, further comprising determining a first neutral current change based on the values of the first neutral current, the third neutral current and the fifth neutral current and a second neutral current change based on the values of the second neural current, the fourth neutral current and the sixth neutral current, wherein the determining whether the source is on the first side of the point of interconnection or the second side of the of the point of interconnection is based on the shunt current, the first neutral current change and the second neutral current change.

9. The method according to claim 8, wherein the first neutral current has a value in₁, the second neutral current has a value in₂, the third neutral current has a value in₃, the fourth neutral current has a value in₄, the fifth neutral current has a value in₅, and the sixth neutral current has a value in₆, wherein the first neutral current change is determined as: [(in₁+in₅)/2]−in₃, and wherein the second neutral current change is determined as: [(in₂+in₆)/2]−in₄.

10. The method according to claim 9, further comprising determining a first sensitivity value comprising a first ratio of the first neutral current change to the shunt current and a second sensitivity value comprising a second ratio of the second neutral current change to the shunt current, wherein the determining whether the source is on the first side of the point of interconnection or the second side of the of the point of interconnection is based on the first sensitivity value and the second sensitivity value.

11. The method according to claim 10, further comprising determining that the source is on the first side of the point of interconnection if the absolute value of the first sensitivity value is greater than or equal to a coefficient times the absolute value of the second sensitivity value, and determining that the source is on the second side of the point of interconnection if the absolute value of the second sensitivity value is greater than or equal to the coefficient times the absolute value of the first sensitivity value.

12. The method according to claim 11, wherein the coefficient equals 4.

13. The method according to claim 11, wherein the coefficient equals 10.

14. The method according to claim 10, further comprising determining that the source is on the first side of the point of interconnection if the absolute value of the first sensitivity value is greater than or equal to a coefficient times the absolute value of the second sensitivity value and if the absolute value of the first sensitivity value is greater than or equal to a constant, and determining that the source is on the second side of the point of interconnection if the absolute value of the second sensitivity value is greater than or equal to the coefficient times the absolute value the first sensitivity value and if the second sensitivity value is greater than or equal to the constant.

15. The method according to claim 14, wherein the coefficient equals 4 and the constant equals 0.6.

16. The method according to claim 14, wherein the coefficient equals 10 the constant equals 0.6.

17. The method according to claim 1, wherein the neutral current values are in the time domain.

18. The method according to claim 1, wherein the neutral current values are in the phasor domain.

19. The method according to claim 1, wherein the zero-sequence circuit includes a zig-zag transformer and a cascade multilevel modular inverter (CMMI) connected in series.

20. The method according to claim 2, wherein the values of the first side neutral currents and the second side neutral currents are obtained using current sensors that are local to the point of interconnection.

21. The method according to claim 2, wherein the values of the first side neutral currents and the second side neutral currents are obtained by receiving the values from a source that is remote from the point of interconnection.

22. The method according to claim 1, wherein the zero-sequence circuit includes a zig-zag transformer and a controllable AC voltage source connected in series.

23. A computer program product, comprising a non-transitory computer usable medium having a computer readable program code embodied therein, the computer readable program code being adapted to be executed to implement a method of identifying a source as recited in claim 1.

24. A system for identifying a source in a three-phase power system including three phase lines and a neutral line, comprising:
a zero-sequence circuit coupled between the three phase lines and the neutral line at a point of interconnection, wherein the zero-sequence circuit is configured to inject current into the point of interconnection; and
a controller coupled to the zero-sequence circuit, the controller being structured and configured for:
causing the zero-sequence circuit to: (i) inject a known shunt current change into the point of interconnection and (ii) cease injection of the known shunt current change into the point of interconnection;
obtaining neutral current values while the known shunt current change is injected and at least one of (i) before the known shunt current change is injected and (ii) after the known shunt current change is injected and ceased; and
determining whether the source is on the first side of the point of interconnection or the second side of the point of interconnection based on the known shunt current change and the neutral current values.

25. The system according to claim 24, wherein the obtaining comprises obtaining values of first side neutral currents on a first side of the point of interconnection while the known shunt current change is injected and the neutral current values obtained either before or after the known shunt current change is injected and obtaining values of second side neutral currents on a second side of the point of interconnection while the known shunt current change is injected and the neutral current values obtained either before or after the known shunt current change is injected, and determining a first neutral current change based on the values of the first side neutral currents and a second neutral current change based on the values of the second side neutral currents, wherein the determining comprises determining whether the source is on the first side of the point of interconnection or the second side of the of the point of interconnection based on the known shunt current change and the first and second neutral current changes.

26. The system according to claim 24, wherein the obtaining comprises obtaining neutral current values: (i) before the known shunt current change is injected, (ii) while the known shunt current change is injected, and (iii) after the known shunt current change is injected and ceased.

27. The system according to claim 24, wherein the obtaining comprises obtaining values of first side neutral currents on a first side of the point of interconnection: (i) before the known shunt current change is injected, (ii) while the known shunt current change is injected, and (iii) after the known shunt current change is injected and ceased and obtaining values of second side neutral currents on a second side of the point of interconnection: (i) before the known shunt current change is injected, (ii) while the known shunt current change is injected, and (iii) after the known shunt current change is injected and ceased; and wherein the determining comprises determining whether the source is on the first side of the point of interconnection or the second side of the of the point of interconnection based on the known shunt current change, the values of the first side neutral currents and the values of the second side neutral currents.

28. The system according to claim 27, wherein the values of the first side neutral currents and the values of the second side neutral currents are each either measured by a current sensor or received from a remote source.

29. The system according to claim 27, wherein the values of the first side neutral currents are each either measured by a current sensor or received from a remote source, and wherein the values of the second side neutral currents are obtained using the first side neutral currents, the known shunt current and Kirchhoff's law.

30. The system according to claim 27, wherein in the controller the causing step, the obtaining steps and the determining step comprise:
obtaining values of a first neutral current on the first side of the point of interconnection and a second neutral current on the second side of the point of interconnection when no current is being injected into the point of interconnection;
injecting a shunt current having a known value into the point of interconnection and obtaining values of a third neutral current on the first side of the point of interconnection and a fourth neutral current on the second side of the point of interconnection during the injection of the shunt current;
terminating the injection of the shunt current and obtaining values of a fifth neutral current on the first side of the point of interconnection and a sixth neutral current on the second side of the point of interconnection when no current is being injected into the point of interconnection; and
determining whether the source is on the first side of the point of interconnection or the second side of the of the point of interconnection based on the shunt current, and the values of the first neutral current, the second neutral current, the third neutral current, the fourth neutral current, the fifth neutral current and the sixth neutral current.

31. The system according to claim 30, wherein the controller is further configured for determining a first neutral current change based on the values of the first neutral current, the third neutral current and the fifth neutral current and a second neutral current change based on the values of the second neural current, the fourth neutral current and the sixth neutral current, wherein the determining whether the source is on the first side of the point of interconnection or the second side of the of the point of interconnection is based on the shunt current, the first neutral current change and the second neutral current change.

32. The system according to claim 31, wherein the first neutral current has a value in₁, the second neutral current has a value in₂, the third neutral current has a value in₃, the fourth neutral current has a value in₄, the fifth neutral current has a value in₅, and the sixth neutral current has a value in₆, wherein the first neutral current change is determined as: [(in₁+in₅)/2]−in₃, and wherein the second neutral current change is determined as: [(in₂+in₆)/2]−in₄.

33. The system according to claim 32, wherein the controller is further configured for determining a first sensitivity value comprising a first ratio of the first neutral current change to the shunt current and a second sensitivity value comprising a second ratio of the second neutral current change to the shunt current, wherein the determining whether the source is on the first side of the point of interconnection or the second side of the of the point of interconnection is based on the first sensitivity value and the second sensitivity value.

34. The system according to claim 33, wherein the controller is further configured for determining that the source is on the first side of the point of interconnection if the absolute value of the first sensitivity value is greater than or equal to a coefficient times the absolute value of the second sensitivity value, and determining that the source is on the second side of the point of interconnection if the absolute value of the second sensitivity value is greater than or equal to the coefficient times the absolute value of the first sensitivity value.

35. The system according to claim 34, wherein the coefficient equals 4.

36. The system according to claim 34, wherein the coefficient equals 10.

37. The system according to claim 33, wherein the controller is further configured for determining that the source is on the first side of the point of interconnection if the absolute value of the first sensitivity value is greater than or equal to a coefficient times the absolute value of the second sensitivity value and if the absolute value of the first sensitivity value is greater than or equal to a constant, and determining that the source is on the second side of the point of interconnection if the absolute value of the second sensitivity value is greater than or equal to the coefficient times the absolute value the first sensitivity value and if the second sensitivity value is greater than or equal to the constant.

38. The system according to claim 37, wherein the coefficient equals 4 and the constant equals 0.6.

39. The system according to claim 37, wherein the coefficient equals 10 the constant equals 0.6.

40. The system according to claim 24, wherein the neutral current values are in the time domain.

41. The system according to claim 24, wherein the neutral current values are in the phasor domain.

42. The system according to claim 24, wherein the zero-sequence circuit includes a zig-zag transformer and a cascade multilevel modular inverter (CMMI) connected in series.

43. The system according to claim 25, wherein values of the first side neutral currents and the second side neutral currents are obtained using current sensors that are local to the point of interconnection.

44. The system according to claim 25, wherein the values of the first side neutral currents and the second side neutral currents are obtained by receiving the values from a source that is remote from the point of interconnection.

45. The system according to claim 24, wherein the zero-sequence circuit includes a zig-zag transformer and a controllable AC voltage source connected in series.

46. The method according to claim 1, wherein the known shunt current injected into the point of interconnection is superimposed on another current present at the point of interconnection.

47. The method according to claim 46, wherein the another current present at the point of interconnection is for reducing a neutral current supplied by the source.
